(19) United States
(12) Patent Application Publication
(10) Pub. No.: US 2010/0301381 A1
(43) Pub. Date: Dec. 2, 2010

(54) NITRIDE SEMICONDUCTOR LIGHT EMITTING ELEMENT AND MANUFACTURING METHOD THEREOF

(75) Inventor: Akihiro URATA, Osaka-shi (JP)

Correspondence Address: MORRISON & FOERSTER LLP, 1650 TYSONS BOULEVARD, SUITE 400, MCLEAN, VA, 22102, US

(73) Assignee: SHARP KABUSHIKI KAISHA, Osaka-shi (JP)

(21) Appl. No.: 12/784,223

(22) Filed: May 20, 2010

(30) Foreign Application Priority Data
May 28, 2009 (JP) 2009-129138

(51) Int. Cl. H01L 33/02; H01L 33/00

(52) U.S. Cl. 257/103; 438/42; 257/E33.002; 257/E33.055

(57) ABSTRACT

Provided are a nitride semiconductor light emitting element, including an n-type nitride semiconductor substrate including a dislocation bundle concentration region, and a nitride semiconductor stacked body having an n-type nitride semiconductor layer, an active layer, and a p-type nitride semiconductor layer in this order on the n-type nitride semiconductor substrate, the nitride semiconductor light emitting element having a dielectric region in a region of the nitride semiconductor stacked body corresponding to the dislocation bundle concentration region, an electrode for p-type provided to be in contact with a portion of the p-type nitride semiconductor layer and a portion of the dielectric region, and an electrode for n-type provided on a side of the n-type nitride semiconductor substrate opposite to a side on which the nitride semiconductor stacked body is provided, and a manufacturing method thereof.

This nonprovisional application is based on Japanese Patent Application No. 2009-129138 filed on May 28, 2009 with the Japan Patent Office, the entire contents of which are hereby incorporated by reference.

### BACKGROUND OF THE INVENTION

1. Field of the Invention

The present invention relates to a nitride semiconductor light emitting element and a manufacturing method thereof.

2. Description of the Background Art

A semiconductor light emitting element utilizing light emission generated by applying a voltage to the semiconductor light emitting element in which an n-type compound semiconductor layer and a p-type compound semiconductor layer are joined with an active layer interposed therebetween, and thereby recombining an electron included in the n-type compound semiconductor layer with a hole included in the p-type compound semiconductor layer has been conventionally known.

As a semiconductor light emitting element, for example, light emitting diode (LED) elements are commercially available. Since a light emitting diode element utilizes a direct transition type semiconductor in which an electron and a hole are recombined efficiently, it has an extremely high light emission efficiency. Accordingly, light emitting diode elements are utilized at present for a display of a home electric appliance, indication at a traffic signal on the road, illumination, and the like.

A white light emitting diode apparatus used for the display and illumination described above is fabricated by combining a blue light emitting diode element with a phosphor such as YAG (yttrium aluminum garnet) having a fluorescence wavelength in a yellow region.

Here, as a blue light emitting diode element, a stacked body of nitride semiconductor layers is used. The stacked body of nitride semiconductor layers generally put into practical use as a blue light emitting diode element has a structure in which an n-type GaN layer, an active layer, and a p-type GaN layer are stacked in order on a sapphire substrate. Since the sapphire substrate is an insulator, etching is performed to reach at least the n-type GaN layer from the p-type GaN layer, and an electrode for n-type in ohmic contact with the n-type GaN layer is provided on an exposed surface of the n-type GaN layer.

Further, a blue light emitting diode element using a gallium nitride (GaN) substrate instead of the sapphire substrate described above has also been proposed in recent years (see for example Patent Document 1 (Japanese Patent Laying-Open No. 2006-156509)).

FIG. 16A shows a schematic plan view of an n-type GaN substrate used to fabricate a GaN-based LED described in Patent Document 1 as one type of a conventional blue light emitting diode element, and FIG. 16B shows a schematic cross sectional view taken along XVIb-XVIb in FIG. 16A.

As shown in FIG. 16A, on a surface of an n-type GaN substrate 101 used to fabricate the GaN-based LED described in Patent Document 1, dislocation bundle concentration regions 108 in the shape of lines extending in one direction are periodically disposed. As shown in FIG. 16B, side surfaces of dislocation bundle concentration region 108 are inclined with respect to the surface of n-type GaN substrate 101. The GaN-based LED described in Patent Document 1 is fabricated in a surface region of the n-type GaN substrate surrounded by a broken line in FIG. 16A.

FIG. 17A shows a schematic plan view of the GaN-based LED described in Patent Document 1, and FIG. 17B shows a schematic cross sectional view taken along XVIIb-XVIIb in FIG. 17A.

The GaN-based LED described in Patent Document 1 has a structure in which an n-type GaN-based semiconductor layer 102, an active layer 103; and a p-type GaN-based semiconductor layer 104 are stacked in this order on the surface of n-type GaN substrate 101 shown in FIGS. 16A and 16B, a p-side electrode 106 is formed on a surface of p-type GaN-based semiconductor layer 104, and an n-side electrode 105 is formed on a surface of n-type GaN-based semiconductor layer 102 to surround a portion of the periphery of p-side electrode 106.

In the GaN-based LED described in Patent Document 1, a portion of n-type GaN-based semiconductor layer 102, active layer 103, and p-type GaN-based semiconductor layer 104 located above dislocation bundle concentration regions 108 of n-type GaN substrate 101 are removed respectively, and n-side electrode 105 is formed in a surface region of n-type GaN-based semiconductor layer 102 located above dislocation bundle concentration regions 108.

In the GaN-based LED described in Patent Document 1 having the structure as described above, a light emitting region, which is a region of active layer 103 located below p-side electrode 106, is not located above dislocation bundle concentration region 108. Therefore, it is intended that an adverse effect on the element such as a short circuit failure due to dislocation bundle concentration region 108 can be prevented, and that a series resistance between n-side electrode 105 and n-type GaN-based semiconductor layer 102 is reduced, and thus an operating voltage for the element can be reduced.

### SUMMARY OF THE INVENTION

In the GaN-based LED described in Patent Document 1, however, it has been necessary to secure a fully wide region between n-side electrode 105 and active layer 103 to prevent occurrence of a current leak between n-side electrode 105 and active layer 103 when n-side electrode 105 is formed in the surface region of n-type GaN-based semiconductor layer 102 above dislocation bundle concentration regions 108. Therefore, in the GaN-based LED described in Patent Document 1, there has been a problem that active layer 103 formed within one element has a small area, and thus it is impossible to increase the area of the light emitting region of the element.

In view of the above circumstances, one object of the present invention is to provide a nitride semiconductor light emitting element having a nitride semiconductor substrate including a dislocation bundle concentration region, in which a light emitting region of the element can have a larger area, and a manufacturing method thereof.

The present invention is a nitride semiconductor light emitting element, including an n-type nitride semiconductor substrate including a dislocation bundle concentration region, and a nitride semiconductor stacked body having an n-type nitride semiconductor layer, an active layer, and a p-type nitride semiconductor layer in this order on the n-type nitride semiconductor substrate, the nitride semiconductor light emitting element having a dielectric region in a region of the nitride semiconductor stacked body corresponding to the dislocation bundle concentration region, an electrode for p-type provided to be in contact with a portion of the p-type nitride semiconductor layer and a portion of the dielectric region, and an electrode for n-type provided on a side of the n-type nitride semiconductor substrate opposite to a side on which the nitride semiconductor stacked body is provided.

Preferably, in the nitride semiconductor light emitting element of the present invention, a surface of the dislocation bundle concentration region is formed in a shape of at least one of a dot and a line.

Preferably, in the nitride semiconductor light emitting element of the present invention, at least a portion of the electrode for p-type is disposed along the dielectric region.

Preferably, in the nitride semiconductor light emitting element of the present invention, the dielectric region includes a single-layer film including at least one dielectric selected from a group consisting of silicon oxide, silicon nitride, aluminum nitride, aluminum oxide, titanium oxide, tantalum oxide, niobium oxide, zirconium oxide, and hafnium oxide, or a multi-layer film formed by stacking a plurality of the single-layer films.

Further, in the nitride semiconductor light emitting element of the present invention, the dislocation bundle concentration regions may be periodically disposed in a surface of the n-type nitride semiconductor substrate. Preferably, the dislocation bundle concentration regions are disposed at a periodic interval of not less than 100 μm and not more than 1000 μm.

Further, in the nitride semiconductor light emitting element of the present invention, the dislocation bundle concentration regions may be randomly disposed in a surface of the n-type nitride semiconductor substrate.

The present invention is a method of manufacturing any of the nitride semiconductor light emitting elements described above, including forming the nitride semiconductor stacked body by stacking the n-type nitride semiconductor layer, the active layer, and the p-type nitride semiconductor layer in this order on the n-type nitride semiconductor substrate including the dislocation bundle concentration region; forming a hole in the nitride semiconductor stacked body by etching the region of the nitride semiconductor stacked body corresponding to the dislocation bundle concentration region; and forming the dielectric region by embedding a dielectric in the hole in the nitride semiconductor stacked body.

Preferably, in the method of manufacturing the nitride semiconductor light emitting element of the present invention, the etching is performed by wet-etching the nitride semiconductor stacked body using an aqueous solution of potassium hydroxide.

According to the present invention, a nitride semiconductor light emitting element having a nitride semiconductor substrate including a dislocation bundle concentration region, in which a light emitting region of the element can have a larger area, and a manufacturing method thereof can be provided.

The foregoing and other objects, features, aspects and advantages of the present invention will become apparent from the following detailed description of the present invention when taken in conjunction with the accompanying drawings.

### BRIEF DESCRIPTION OF THE DRAWINGS

FIG. 1A is a schematic plan view of a nitride semiconductor light emitting diode element of Embodiment 1 as an exemplary nitride semiconductor light emitting element of the present invention.

FIG. 1B is a schematic cross sectional view taken along Ib-Ib in FIG. 1A.

FIG. 2A is a schematic plan view of an exemplary n-type nitride semiconductor substrate used to manufacture the nitride semiconductor light emitting diode element of Embodiment 1.

FIG. 2B is a schematic cross sectional view taken along IIb-IIb in FIG. 2A.

FIG. 3 is a schematic cross sectional view illustrating a portion of a manufacturing process of an exemplary method of manufacturing the nitride semiconductor light emitting diode element of Embodiment 1.

FIG. 4 is a schematic cross sectional view illustrating another portion of the manufacturing process of the exemplary method of manufacturing the nitride semiconductor light emitting diode element of Embodiment 1.

FIG. 5 is a schematic cross sectional view illustrating another portion of the manufacturing process of the exemplary method of manufacturing the nitride semiconductor light emitting diode element of Embodiment 1.

FIG. 6 is a schematic cross sectional view illustrating another portion of the manufacturing process of the exemplary method of manufacturing the nitride semiconductor light emitting diode element of Embodiment 1.

FIG. 7 is a schematic plan view of an exemplary surface of a nitride semiconductor stacked body after forming a dielectric region in the nitride semiconductor light emitting diode element of Embodiment 1.

FIG. 8 is a schematic cross sectional view illustrating another portion of the manufacturing process of the exemplary method of manufacturing the nitride semiconductor light emitting diode element of Embodiment 1.

FIG. 9A is a schematic plan view of a nitride semiconductor light emitting diode element of Embodiment 2 as another exemplary nitride semiconductor light emitting element of the present invention.

FIG. 9B is a schematic cross sectional view taken along IXb-IXb in FIG. 9A.

FIG. 10A is a schematic plan view of an exemplary n-type nitride semiconductor substrate used to manufacture the nitride semiconductor light emitting diode element of Embodiment 2.

FIG. 10B is a schematic cross sectional view taken along Xb-Xb in FIG. 10A.

FIG. 11 is a schematic cross sectional view of a wafer during manufacturing of the nitride semiconductor light emitting diode element of Embodiment 2.

FIG. 12A is a schematic plan view of a nitride semiconductor light emitting diode element of Embodiment 3 as another exemplary nitride semiconductor light emitting element of the present invention.

FIG. 12B is a schematic cross sectional view taken along XIIb-XIIb in FIG. 12A.

FIG. 13 is a schematic cross sectional view of a nitride semiconductor light emitting diode element of Embodiment 4 as another exemplary nitride semiconductor light emitting element of the present invention.

FIG. 14A is a schematic plan view of an exemplary n-type nitride semiconductor substrate used to manufacture the nitride semiconductor light emitting diode element of Embodiment 4.

FIG. 14B is a schematic cross sectional view taken along XIVb-XIVb in FIG. 14A.

FIG. 15 is a schematic cross sectional view of a wafer during manufacturing of the nitride semiconductor light emitting diode element of Embodiment 4.

FIG. 16A is a schematic plan view of an n-type GaN substrate used to fabricate a GaN-based LED described in Patent Document 1 as one type of a conventional blue light emitting diode element.

FIG. 16B is a schematic cross sectional view taken along XVIb-XVIb in FIG. 16A.

FIG. 17A is a schematic plan view of the GaN-based LED described in Patent Document 1.

FIG. 17B is a schematic cross sectional view taken along XVIIb-XVIIb in FIG. 17A.

### DESCRIPTION OF THE PREFERRED EMBODIMENTS

Hereinafter, embodiments of the present invention will be described. In the drawings of the present invention, identical or corresponding parts will be designated by the same reference numerals.

### Embodiment 1

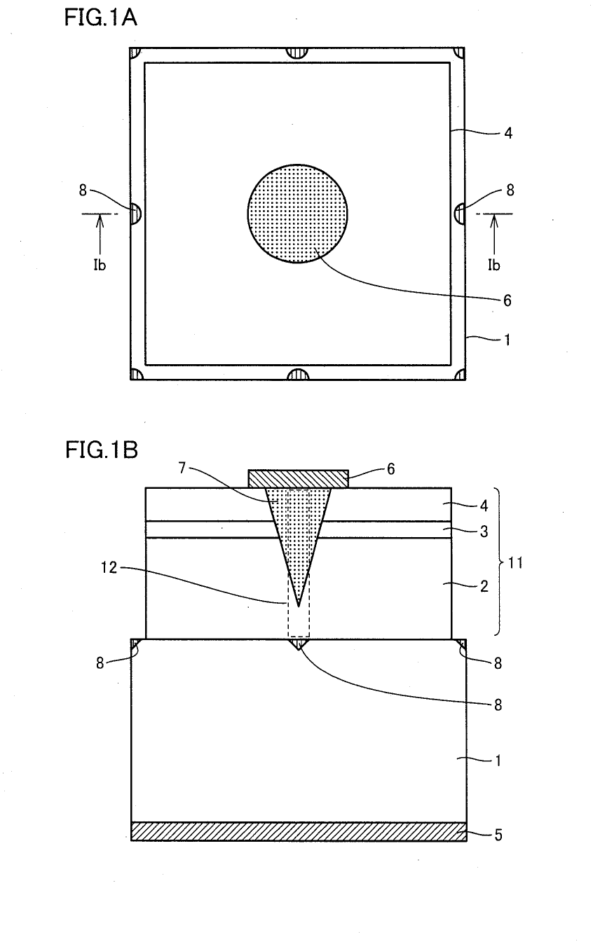

FIG. 1A shows a schematic plan view of a nitride semiconductor light emitting diode element of Embodiment 1 as an exemplary nitride semiconductor light emitting element of the present invention, and FIG. 1B shows a schematic cross sectional view taken along Ib-Ib in FIG. 1A.

As shown in FIG. 1B, the nitride semiconductor light emitting diode element of Embodiment 1 has an n-type nitride semiconductor substrate 1 having a dislocation bundle concentration region 8, and a nitride semiconductor stacked body 11 formed by stacking an n-type nitride semiconductor layer 2, an active layer 3, and a p-type nitride semiconductor layer 4 in this order on a surface of n-type nitride semiconductor substrate 1 in which dislocation bundle concentration region 8 is formed.

A dielectric region 7 as a region in which a dielectric is embedded is formed in a portion of a region 12 (a region surrounded by a broken line in FIG. 1B) of nitride semiconductor stacked body 11 corresponding to dislocation bundle concentration region 8.

Further, an electrode for p-type 6 is formed along a portion of a surface of p-type nitride semiconductor layer 4 and a surface of dielectric region 7 serving as the uppermost surface of nitride semiconductor stacked body 11. An electrode for n-type 5 is formed on a surface of n-type nitride semiconductor substrate 1 on a side opposite to a side on which nitride semiconductor stacked body 11 is formed (i.e., on a surface on a side opposite to a side on which dislocation bundle concentration region 8 is formed). Electrode for p-type 6 is in ohmic contact with p-type nitride semiconductor layer 4, and electrode for n-type 5 is in ohmic contact with n-type nitride semiconductor substrate 1.

Furthermore, as shown in FIG. 1A, dot-like dislocation bundle concentration regions 8 are exposed in a peripheral portion of the surface of n-type nitride semiconductor substrate 1 exposed from nitride semiconductor stacked body 11.

As n-type nitride semiconductor substrate 1, for example, a substrate made of a conventionally known n-type nitride semiconductor can be used. For example, a substrate formed by doping a nitride semiconductor crystal represented by a formula Alₓ₁In_{y1}Ga_{z1}N (0≦x1≦1, 0≦y1≦1, 0≦z1≦1, x1+y1+z1≠0) with n-type impurities can be used. It is to be noted that, in the formula described above, Al represents aluminum, In represents indium, Ga represents gallium, x1 represents a composition ratio of Al, y1 represents a composition ratio of In, and z1 represents a composition ratio of Ga. Further, as the n-type impurities, for example, silicon and/or germanium or the like can be used.

Here, dislocation bundle concentration region 8 is a region in which crystal defects are localized in the surface of n-type nitride semiconductor substrate 1, and can be identified for example by observing with an optical microscope or the like.

As n-type nitride semiconductor layer 2, for example, a conventionally known n-type nitride semiconductor can be used. For example, a single layer or a plurality of layers formed by doping a nitride semiconductor crystal represented by a formula Alₓ₂In_{y2}Ga_{z2}N (0≦x2≦1, 0≦y2≦1, 0≦z2≦1, x2+y2+z2≠0) with n-type impurities can be used. It is to be noted that, in the formula described above, Al represents aluminum, In represents indium, Ga represents gallium, x2 represents a composition ratio of Al, y2 represents a composition ratio of In, and z2 represents a composition ratio of Ga. Further, as the n-type impurities, for example, silicon and/or germanium or the like can be used.

As active layer 3, for example, a conventionally known nitride semiconductor can be used. For example, a single layer or a plurality of layers formed of an undoped nitride semiconductor crystal represented by a formula Alₓ₃In_{y3}Ga_{z3}N (0≦x3≦1, 0≦y3≦1, 0≦z3≦1, x3+y3+z3≠0) or a nitride semiconductor crystal represented by the formula doped with at least one of p-type impurities and n-type impurities can be used. It is to be noted that, in the formula described above, Al represents aluminum, In represents indium, Ga represents gallium, x3 represents a composition ratio of Al, y3 represents a composition ratio of In, and z3 represents a composition ratio of Ga. Further, active layer 3 may be configured to have a conventionally known single quantum well (SQW) structure or multiple quantum well (MQW) structure.

As p-type nitride semiconductor layer 4, for example, a conventionally known p-type nitride semiconductor can be used. For example, a single layer or a plurality of layers formed by doping a nitride semiconductor crystal represented by a formula Alₓ₄In_{y4}Ga_{z4}N (0≦x4≦1, 0≦y4≦1, 0≦z4≦1, x4+y4+z4≠0) with p-type impurities can be used. It is to be noted that, in the formula described above, Al represents aluminum, In represents indium, Ga represents gallium, x4 represents a composition ratio of Al, y4 represents a composition ratio of In, and z4 represents a composition ratio of Ga. Further, as the p-type impurities, for example, magnesium and/or zinc or the like can be used.

As electrode for n-type 5, for example, a single metal layer including at least one selected from a group consisting of Au (gold), Ag (silver), Pt (platinum), Ti (titanium), Pd (palladium), Al (aluminum), and Ni (nickel), or a plurality of layers formed by stacking a plurality of the single metal layers can be used.

As electrode for p-type 6, for example, a single metal layer including at least one selected from a group consisting of Au, Ag, Pt, Ti, Pd, Al, and Ni, or a plurality of layers formed by stacking a plurality of the single metal layers can be used.

As a dielectric used for dielectric region 7, a conventionally known dielectric can be used. For example, a single-layer film including a dielectric selected from a group consisting of silicon oxide, silicon nitride, aluminum nitride, aluminum oxide, titanium oxide, tantalum oxide, niobium oxide, zirconium oxide, and hafnium oxide, or a multi-layer film formed by stacking a plurality of the single-layer films can be used.

The nitride semiconductor light emitting diode element of Embodiment 1 can be manufactured, for example, as described below.

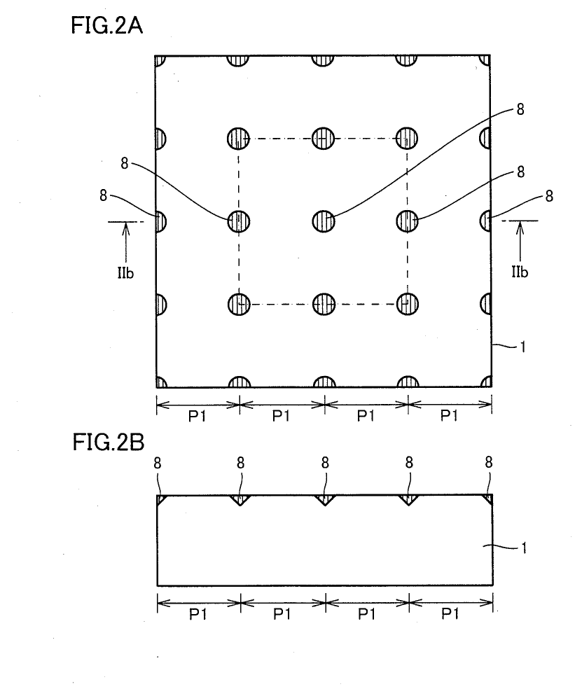

Firstly, n-type nitride semiconductor substrate 1 having a structure shown in FIGS. 2A and 2B is prepared. FIG. 2A shows a schematic plan view of n-type nitride semiconductor substrate 1 used to manufacture the nitride semiconductor light emitting diode element of Embodiment 1, and FIG. 2B shows a schematic cross sectional view taken along IIb-IIb in FIG. 2A. A region surrounded by a broken line in FIG. 2A represents a surface region of n-type nitride semiconductor substrate 1 in which the nitride semiconductor light emitting diode element of Embodiment 1 is formed.

A plurality of dot-like dislocation bundle concentration regions 8 are formed in the surface of n-type nitride semiconductor substrate 1, and the plurality of dislocation bundle concentration regions 8 formed in the surface of n-type nitride semiconductor substrate 1 are periodically arranged at an interval P1. By periodically disposing dislocation bundle concentration regions 8, an average defect density in a region of nitride semiconductor stacked body 11 other than regions 12 corresponding to dislocation bundle concentration regions 8 can be reduced evenly. Therefore, nitride semiconductor stacked body 11 excellent in crystallinity evenly in the region of nitride semiconductor stacked body 11 other than regions 12 can be fabricated.

Periodic interval P1 between dislocation bundle concentration regions 8 can be set, for example, to be not less than 100 μm and not more than 1000 μm.

It is needless to say that all of periodic intervals P1 between dislocation bundle concentration regions 8 may be identical to be able to say that dislocation bundle concentration regions 8 are periodically arranged in the present invention. However, it is not necessary that all of periodic intervals P1 are identical, as long as an absolute value of a difference between the maximum value and the minimum value of periodic intervals P1 between dislocation bundle concentration regions 8 is not more than 500 μm.

Further, although the shape of the surface of dislocation bundle concentration region 8 is not particularly limited, it is preferable that the surface of dislocation bundle concentration region 8 is in the shape of a dot and/or a line, because there is an increased tendency that the average defect density in the region of nitride semiconductor stacked body 11 other than regions 12 corresponding to dislocation bundle concentration regions 8 can be reduced. It is more preferable that the surface of dislocation bundle concentration region 8 is in the shape of a line, from the viewpoint of further reducing the average defect density in the region of nitride semiconductor stacked body 11 other than regions 12 corresponding to dislocation bundle concentration regions 8.

It is to be noted that the average defect density in nitride semiconductor stacked body 11 is greatly affected by a defect density in region 12 of nitride semiconductor stacked body 11 in which defects continuing from dislocation bundle concentration region 8 in the surface of n-type nitride semiconductor substrate 1 are formed in a concentrated manner (i.e., a defect concentration region).

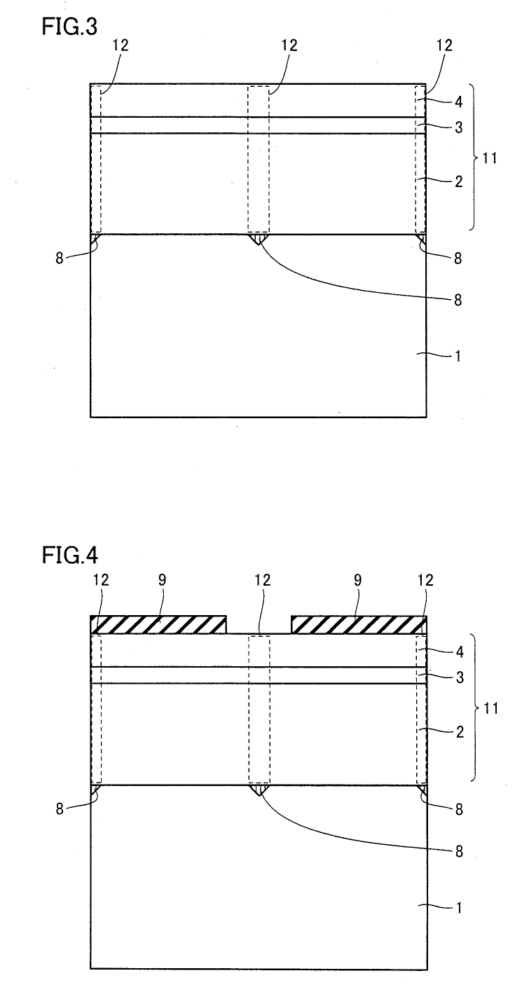

Next, as shown in a schematic cross sectional view of FIG. 3, nitride semiconductor stacked body 11 is formed by stacking n-type nitride semiconductor layer 2, active layer 3, and p-type nitride semiconductor layer 4 in this order on the surface of n-type nitride semiconductor substrate 1 in which dislocation bundle concentration regions 8 are formed.

Here, n-type nitride semiconductor layer 2, active layer 3, and p-type nitride semiconductor layer 4 can be formed, for example, by setting n-type nitride semiconductor substrate 1 in an MOCVD (Metal Organic Chemical Vapor Deposition) apparatus and thereafter growing nitride semiconductor crystals by the MOCVD method.

At the time of growing the respective nitride semiconductor crystals constituting n-type nitride semiconductor layer 2, active layer 3, and p-type nitride semiconductor layer 4, defects are formed in a concentrated manner in region 12 of nitride semiconductor stacked body 11 above dislocation bundle concentration region 8 to continue from dislocation bundle concentration region 8 in the surface of n-type nitride semiconductor substrate 1. Thereby, region 12 of nitride semiconductor stacked body 11 becomes a defect concentration region.

Thereafter, p-type nitride semiconductor layer 4 is annealed by heat-treating a wafer in which nitride semiconductor stacked body 11 is formed on the surface of n-type nitride semiconductor substrate 1.

Subsequently, as shown in a schematic cross sectional view of FIG. 4, a protective mask 9 having a predetermined opening is formed on the surface of nitride semiconductor stacked body 11. The opening is provided in protective mask 9 such that at least a portion of a surface of region 12, which is a defect concentration region, of nitride semiconductor stacked body 11 is exposed.

As protective mask 9, for example, a photoresist, a metal, an insulator, or the like resistant to an etching solution described later can be used.

Next, as shown in a schematic cross sectional view of FIG. 5, a portion of nitride semiconductor stacked body 11 exposed from the opening in protective mask 9 on nitride semiconductor stacked body 11 is etched and removed, and thereby a hole 10 is formed in nitride semiconductor stacked body 11. Thereafter, entire protective mask 9 is removed.

Here, hole 10 is formed in nitride semiconductor stacked body 11 by etching such that a portion of p-type nitride semiconductor layer 4, a portion of active layer 3, and a portion of n-type nitride semiconductor layer 2 are respectively removed in a direction of thickness of nitride semiconductor stacked body 11.

Further, etching of nitride semiconductor stacked body 11 can be performed, for example, by wet etching and/or dry etching, and it is particularly preferable to perform etching of nitride semiconductor stacked body 11 by wet etching using an aqueous solution of potassium hydroxide as an etching solution. When etching of nitride semiconductor stacked body 11 is performed by wet etching using an aqueous solution of potassium hydroxide as an etching solution, there is a tendency that nitride semiconductor stacked body 11 can be etched easily as well as efficiently in a short time. Since region 12 as a defect concentration region of nitride semiconductor stacked body 11 has a high etching rate when compared with a region of nitride semiconductor stacked body 11 above a region other than dislocation bundle concentration region 8 in the surface of n-type nitride semiconductor substrate 1, nitride semiconductor stacked body 11 can be removed by wet etching. In particular, when an etching solution having anisotropy for etching such as an aqueous solution of sodium hydroxide is used, nitride semiconductor stacked body 11 can be etched efficiently.

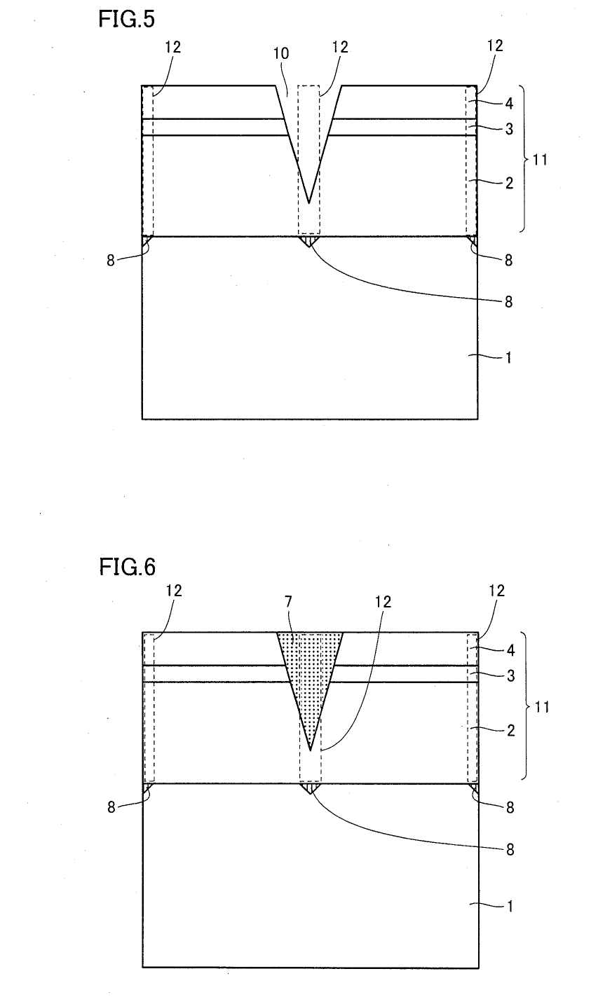

Subsequently, as shown in a schematic cross sectional view of FIG. 6, dielectric region 7 is formed by embedding a dielectric in at least a portion of hole 10 formed in nitride semiconductor stacked body 11.

As the dielectric used to form dielectric region 7, for example, a conventionally known dielectric can be used, and it is particularly preferable to use a single-layer film including at least one dielectric selected from a group consisting of silicon oxide, silicon nitride, aluminum nitride, aluminum oxide, titanium oxide, tantalum oxide, niobium oxide, zirconium oxide, and hathium oxide, or a multi-layer film formed by stacking a plurality of the single-layer films, from the viewpoint of disposing a dielectric having a high insulation effect in hole 10 to prevent current leak from side surfaces of n-type nitride semiconductor layer 2, active layer 3, and p-type nitride semiconductor layer 4 in hole 10.

Dielectric region 7 can be formed, for example, as described below. Firstly, a dielectric made of, for example, a single-layer film of silicon oxide is formed over the entire surface of p-type nitride semiconductor layer 4 serving as the uppermost surface of nitride semiconductor stacked body 11, such that at least a portion of hole 10 is filled. Here, the single-layer film of silicon oxide as a dielectric can be formed, for example, by the plasma chemical vapor deposition (CVD) method or the sputtering method. In particular, the plasma CVD method is preferable to form dielectric region 7 with good insulation properties.

The method of forming a dielectric is not limited to the methods described above, and a dielectric can be formed with a method suitable for each dielectric.

Next, a protective mask such as a photoresist is provided on a surface of the single-layer film of silicon oxide formed as described above. Here, the protective mask is provided to expose a region other than a surface region of the single-layer film of silicon oxide corresponding to dielectric region 7 and cover the surface region of the single-layer film of silicon oxide corresponding to dielectric region 7.

Finally, the region of the single-layer film of silicon oxide exposed from the protective mask is removed with an etching solution such as an aqueous solution of hydrogen fluoride, and thereby dielectric region 7 formed by embedding a dielectric in at least a portion of hole 10 is formed.

The etching solution used to form dielectric region 7 is also not limited to an aqueous solution of hydrogen fluoride, and an etching solution suitable for each dielectric can be used.

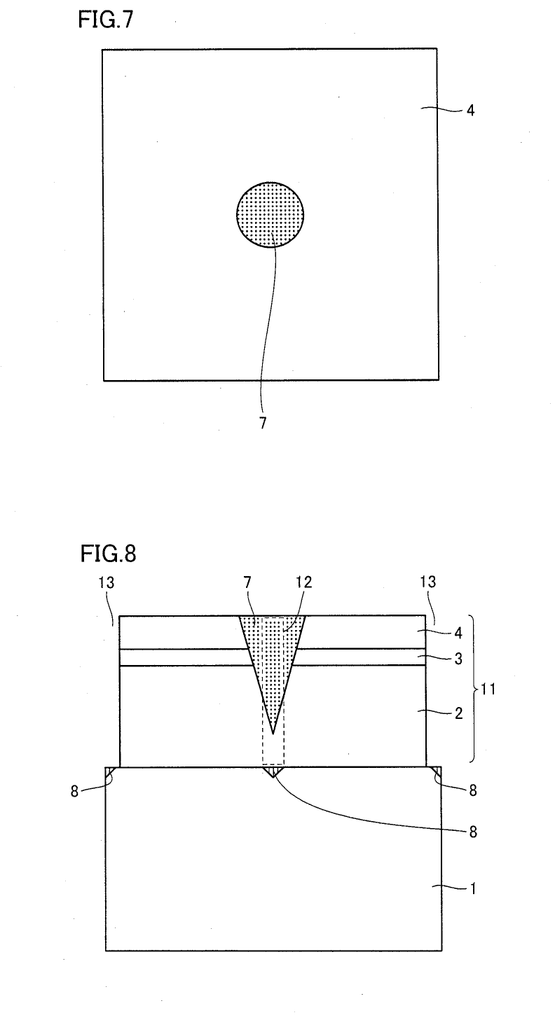

FIG. 7 shows a schematic plan view of the surface of nitride semiconductor stacked body 11 after forming dielectric region 7 described above. Here, dielectric region 7 is provided in the center of the surface of nitride semiconductor stacked body 11, and the surface of dielectric region 7 is formed in the shape of a circle.

Next, as shown in a schematic cross sectional view of FIG. 8, by removing a peripheral region of nitride semiconductor stacked body 11, the surface of n-type nitride semiconductor substrate 1 is exposed, and an element separation groove 13 is formed.

Here, element separation groove 13 can be formed by providing a protective mask having an opening at a peripheral edge of nitride semiconductor stacked body 11 on the surface of nitride semiconductor stacked body 11, and thereafter removing the peripheral edge of nitride semiconductor stacked body 11 by, for example, dry etching or the like.

However, it is not necessary to perform this step in a case where element separation groove 13 is formed simultaneously with the formation of dielectric region 7.

Subsequently, electrode for p-type 6 is formed to cover the surface of dielectric region 7 and also cover a portion of the surface of p-type nitride semiconductor layer 4. Here, electrode for p-type 6 can be formed, for example, by the vacuum deposition method, the sputtering method, or the like.

Next, electrode for n-type 5 is formed over the entire rear surface of n-type nitride semiconductor substrate 1 on a side opposite to the side on which nitride semiconductor stacked body 11 is provided.

Finally, separation into a plurality of chips is performed by scribing with a laser beam or a diamond pen or dicing with a blade along element separation groove 13, and thus the nitride semiconductor light emitting diode element of Embodiment 1 corresponding to each separated chip is fabricated.

Although n-type nitride semiconductor substrate 1 including dislocation bundle concentration region 8 is included in the nitride semiconductor light emitting diode element of Embodiment 1 fabricated as described above, there is no need to provide a region for forming an electrode for n-type by removing p-type nitride semiconductor layer 4, active layer 3, and a portion of n-type nitride semiconductor layer 2 located above dislocation bundle concentration region 8, as in the conventional GaN-based LED described in Patent Document 1. Therefore, a light emitting region in active layer 3 can have a larger area.

Further, in the nitride semiconductor light emitting diode element of Embodiment 1, dielectric region 7 is formed in at least a portion of the defect concentration region (region 12 of nitride semiconductor stacked body 11) serving as a current leak path, and electrode for p-type 6 is formed to be in contact with the surface of dielectric region 7 and a portion of p-type nitride semiconductor layer 4 serving as the uppermost surface of nitride semiconductor stacked body 11. Thereby, electrostatic discharges (ESD) are improved, and thus reliability of the element can be improved.

Furthermore, since dielectric region 7 is formed immediately below electrode for p-type 6 in the nitride semiconductor light emitting diode element of Embodiment 1, a current can be prevented from flowing through a region immediately below electrode for p-type 6. This can prevent occurrence of a situation in which light generated immediately below electrode for p-type 6 is absorbed by electrode for p-type 6 and thus cannot be extracted. Therefore, the nitride semiconductor light emitting diode element can have an improved light extraction efficiency.

In addition, with a decrease in periodic interval P1 between dislocation bundle concentration regions 8, the average defect density in the region other than region 12 of nitride semiconductor stacked body 11 above dislocation bundle concentration region 8 can be reduced, whereas the average defect density in region 12 (the defect concentration region) of nitride semiconductor stacked body 11 above dislocation bundle concentration region 8 is increased. Thus, it becomes difficult to effectively utilize the defect concentration region of nitride semiconductor stacked body 11.

For this reason, in the nitride semiconductor light emitting diode element of Embodiment 1, at least a portion of the defect concentration region (region 12) of nitride semiconductor stacked body 11 immediately above dislocation bundle concentration region 8 is removed by etching to form dielectric region 7, and an electrode for diffusing a current is disposed on dielectric region 7. Thereby, the defect concentration region of nitride semiconductor stacked body 11 can be utilized efficiently.

### Embodiment 2

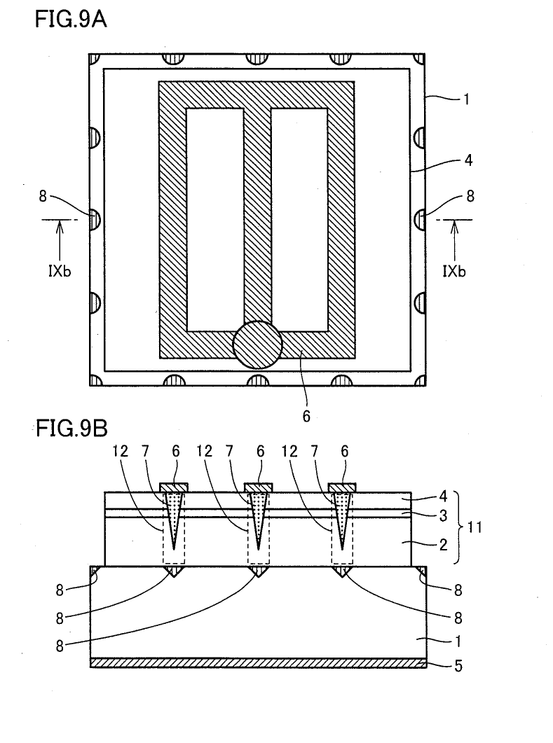

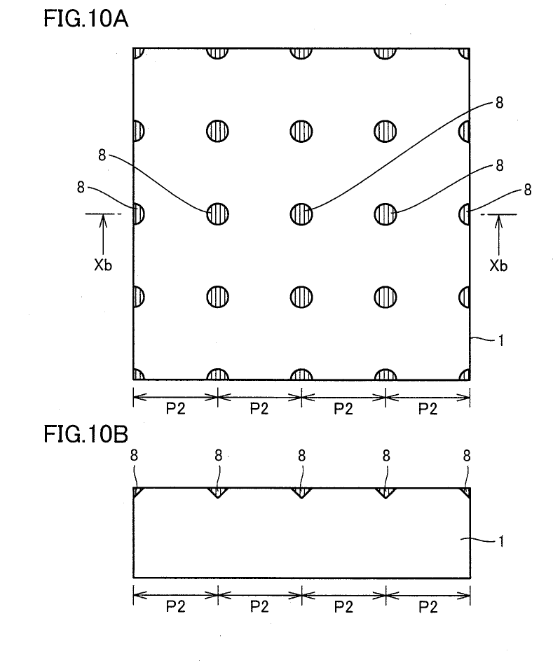

FIG. 9A shows a schematic plan view of a nitride semiconductor light emitting diode element of Embodiment 2 as another exemplary nitride semiconductor light emitting element of the present invention, and FIG. 9B shows a schematic cross sectional view taken along IXb-IXb in FIG. 9A.

The nitride semiconductor light emitting diode element of Embodiment 2 has a structure substantially identical to that of the nitride semiconductor light emitting diode element of Embodiment 1, and is characterized in that the periodic interval between dislocation bundle concentration regions 8 in the surface of n-type nitride semiconductor substrate 1 is smaller than that of the nitride semiconductor light emitting diode element of Embodiment 1.

Since the periodic interval between dislocation bundle concentration regions 8 in the surface of n-type nitride semiconductor substrate 1 is smaller in the nitride semiconductor light emitting diode element of Embodiment 2, the average defect density in the region other than region 12 of nitride semiconductor stacked body 11 corresponding to dislocation bundle concentration region 8 can be further reduced when compared with that of the nitride semiconductor light emitting diode element of Embodiment 1, and thus the light emitting region in active layer 3 excellent in crystal quality can be formed.

In the nitride semiconductor light emitting diode element of Embodiment 2, since the periodic interval between dislocation bundle concentration regions 8 is smaller and thus the periodic interval between dielectric regions 7 is also smaller, the shape of electrode for p-type 6 in contact with the surface of dielectric regions 7 is also changed.

The nitride semiconductor light emitting diode element of Embodiment 2 can be manufactured, for example, as described below.

Firstly, n-type nitride semiconductor substrate 1 having a structure shown in FIGS. 10A and 10B is prepared. FIG. 10A shows a schematic plan view of n-type nitride semiconductor substrate 1 used to manufacture the nitride semiconductor light emitting diode element of Embodiment 2, and FIG. 10B shows a schematic cross sectional view taken along Xb-Xb in FIG. 10A.

The plurality of dot-like dislocation bundle concentration regions 8 are formed in the surface of n-type nitride semiconductor substrate 1, and the plurality of dislocation bundle concentration regions 8 formed in the surface of n-type nitride semiconductor substrate 1 are periodically arranged at an interval P2. Periodic interval P2 between dislocation bundle concentration regions 8 in the present embodiment is smaller than periodic interval P1 between dislocation bundle concentration regions 8 in Embodiment 1.

Since a region surrounded by a rectangular solid line in FIG. 10A having an area larger than the area surrounded by the broken line in FIG. 1A can serve as a surface region of n-type nitride semiconductor substrate 1 in which the nitride semiconductor light emitting diode element of Embodiment 2 is formed, the light emitting region can have a further larger area in the nitride semiconductor light emitting diode element of Embodiment 2, when compared with the nitride semiconductor light emitting diode element of Embodiment 1.

Thereafter, the nitride semiconductor light emitting diode element of Embodiment 2 can be fabricated as with the nitride semiconductor light emitting diode element of Embodiment 1.

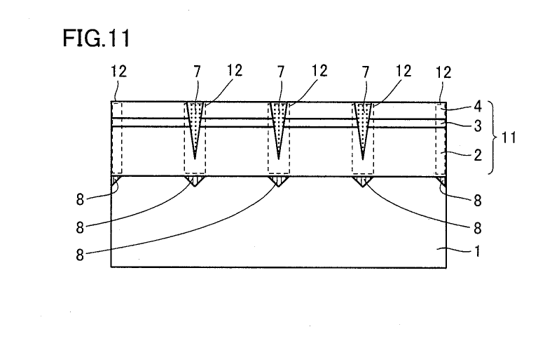

FIG. 11 shows a schematic cross sectional view of a wafer during manufacturing of the nitride semiconductor light emitting diode element of Embodiment 2. The wafer shown in FIG. 11 is formed such that a plurality of (nine in the present embodiment) dielectric regions 7 are provided in each nitride semiconductor light emitting diode element of Embodiment 2.

Since the description other than the above in the present embodiment is the same as that in Embodiment 1, the description will not be repeated here.

### Embodiment 3

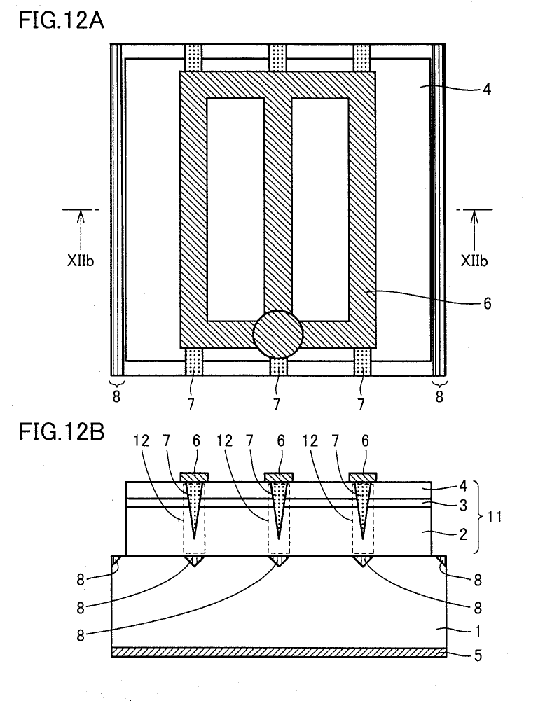

FIG. 12A shows a schematic plan view of a nitride semiconductor light emitting diode element of Embodiment 3 as another exemplary nitride semiconductor light emitting element of the present invention, and FIG. 12B shows a schematic cross sectional view taken along XIIb-XIIb in FIG. 12A.

The nitride semiconductor light emitting diode element of Embodiment 3 is different from the nitride semiconductor light emitting diode element of Embodiment 2 in that the surface of dislocation bundle concentration region 8 in the surface of n-type nitride semiconductor substrate 1 is formed in the shape of a line extending in one direction along the surface of n-type nitride semiconductor substrate 1, instead of a dot.

Since linear dislocation bundle concentration region 8 has a larger area than dot-like dislocation bundle concentration region 8, more defects are concentrated in region 12 of nitride semiconductor stacked body 11 corresponding dislocation bundle concentration region 8, and the average defect density in the region other than region 12 of nitride semiconductor stacked body 11 can be further reduced. Therefore, the light emitting region in active layer 3 further excellent in crystal quality than that of the nitride semiconductor light emitting diode element of Embodiment 2 can be formed.

Further, in the nitride semiconductor light emitting diode element of Embodiment 3, since the surface of dislocation bundle concentration region 8 is in the shape of a line and thus the surface of dielectric region 7 is also in the shape of a line, a current non-injected region having a surface in the shape of aline can be fabricated immediately below linear electrode for p-type 6. Thereby, in the nitride semiconductor light emitting diode element of Embodiment 3, light extraction efficiency can be improved when compared with the nitride semiconductor light emitting diode element of Embodiment 2 in which the surface of dislocation bundle concentration region 8 is in the shape of a dot.

The nitride semiconductor light emitting diode element of Embodiment 3 can be fabricated as in the nitride semiconductor light emitting diode element of Embodiment 2, except for forming the surface of dielectric region 7 in the shape of a line.

Since the description other than the above in the present embodiment is the same as that in Embodiment 2, the description will not be repeated here.

### Embodiment 4

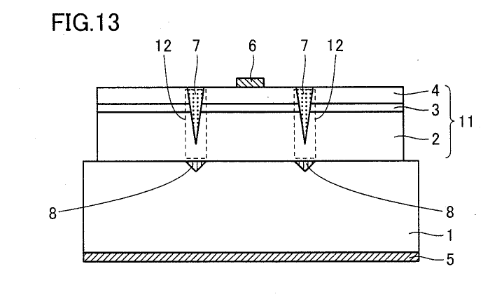

FIG. 13 shows a schematic cross sectional view of a nitride semiconductor light emitting diode element of Embodiment 4 as another exemplary nitride semiconductor light emitting element of the present invention. The nitride semiconductor light emitting diode element of Embodiment 4 is characterized in that dislocation bundle concentration regions 8 are randomly formed in the surface of n-type nitride semiconductor substrate 1.

Although the average defect density in the region other than regions 12 of nitride semiconductor stacked body 11 corresponding to dislocation bundle concentration regions 8 is reduced when compared with n-type nitride semiconductor substrates 1 used in Embodiments 1 to 3 in which the surface of dislocation bundle concentration region 8 in n-type nitride semiconductor substrate 1 is in the shape of a dot and/or a line, n-type nitride semiconductor substrate 1 itself can be obtained at a low cost.

The nitride semiconductor light emitting diode element of Embodiment 4 can be manufactured, for example, as described below.

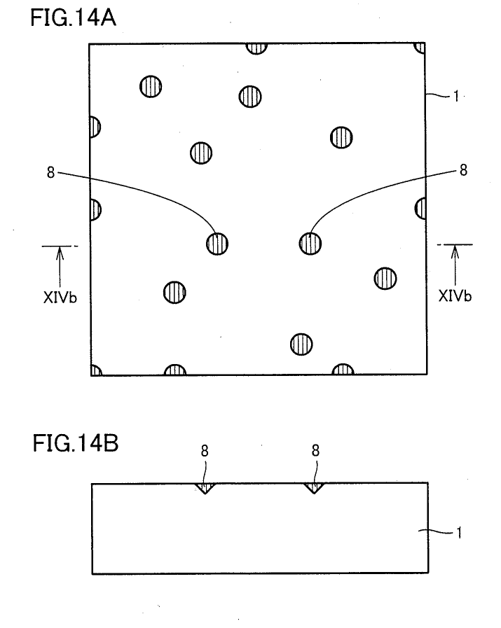

Firstly, n-type nitride semiconductor substrate 1 having a structure shown in FIGS. 14A and 14B is prepared. FIG. 14A shows a schematic plan view of n-type nitride semiconductor substrate 1 used to manufacture the nitride semiconductor light emitting diode element of Embodiment 4, and FIG. 14B shows a schematic cross sectional view taken along XIVb-XIVb in FIG. 14A.

In the surface of n-type nitride semiconductor substrate 1 used to manufacture the nitride semiconductor light emitting diode element of Embodiment 4, the plurality of dot-like dislocation bundle concentration regions 8 are formed randomly.

Thereafter, the nitride semiconductor light emitting diode element of Embodiment 4 can be fabricated as in the nitride semiconductor light emitting diode elements of Embodiments 1 to 3.

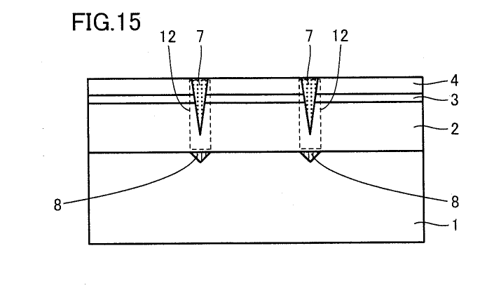

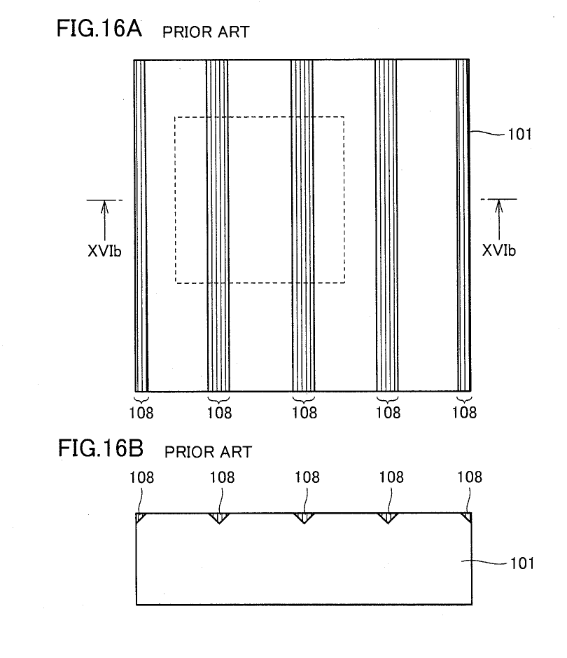

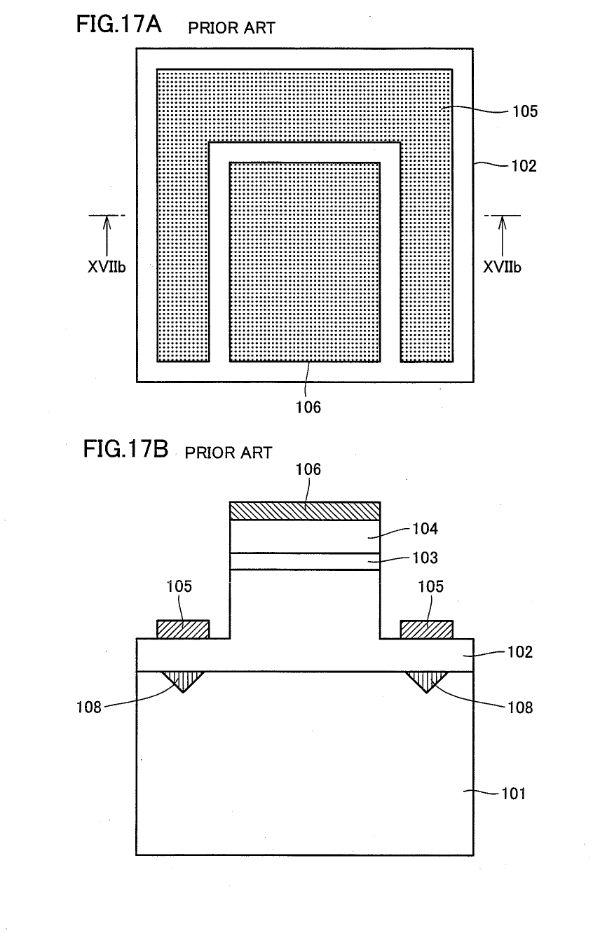

FIG. 15 shows a schematic cross sectional view of a wafer during manufacturing of the nitride semiconductor light emitting diode element of Embodiment 4. In the wafer shown in FIG. 15, dielectric regions 7 are formed in regions located above dot-like dislocation bundle concentration regions 8 randomly formed in the surface of n-type nitride semiconductor substrate 1.

Here, dielectric region 7 can be formed, for example, by forming a hole by removing region 12 of nitride semiconductor stacked body 11 serving as a current leak path by wet etching using an etching solution such as an aqueous solution of potassium hydroxide, or the like, and embedding a dielectric such as silicon oxide in the hole.

Further, the dielectric can be embedded, for example, by forming a dielectric layer of such as silicon oxide over the entire surface of nitride semiconductor stacked body 11 having the hole described above formed therein, and thereafter removing the dielectric layer on the surface of nitride semiconductor stacked body 11 by chemical mechanical polishing (CMP) or the like to leave only the dielectric layer embedded in the hole.

Since the description other than the above in the present embodiment is the same as those in Embodiments 1 to 3, the description will not be repeated here.

The present invention is applicable to a nitride semiconductor light emitting element and a manufacturing method thereof, and in particular suitably applicable to a nitride semiconductor light emitting diode element and a manufacturing method thereof.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A nitride semiconductor light emitting element, comprising
an n-type nitride semiconductor substrate including a dislocation bundle concentration region; and
a nitride semiconductor stacked body having an n-type nitride semiconductor layer, an active layer, and a p-type nitride semiconductor layer in this order on said n-type nitride semiconductor substrate,
said nitride semiconductor light emitting element having
a dielectric region in a region of said nitride semiconductor stacked body corresponding to said dislocation bundle concentration region,
an electrode for p-type provided to be in contact with a portion of said p-type nitride semiconductor layer and a portion of said dielectric region, and
an electrode for n-type provided on a side of said n-type nitride semiconductor substrate opposite to a side on which said nitride semiconductor stacked body is provided.

2. The nitride semiconductor light emitting element according to claim 1, wherein a surface of said dislocation bundle concentration region is formed in a shape of at least one of a dot and a line.

3. The nitride semiconductor light emitting element according to claim 1, wherein at least a portion of said electrode for p-type is disposed along said dielectric region.

4. The nitride semiconductor light emitting element according to claim 1, wherein said dielectric region includes a single-layer film including at least one dielectric selected from a group consisting of silicon oxide, silicon nitride, aluminum nitride, aluminum oxide, titanium oxide, tantalum oxide, niobium oxide, zirconium oxide, and hafnium oxide, or a multi-layer film formed by stacking a plurality of said single-layer films.

5. The nitride semiconductor light emitting element according to claim 1, wherein said dislocation bundle concentration regions are periodically disposed in a surface of said n-type nitride semiconductor substrate.

6. The nitride semiconductor light emitting element according to claim 5, wherein said dislocation bundle concentration regions are disposed at a periodic interval of not less than 100 μm and not more than 1000 μm.

7. The nitride semiconductor light emitting element according to claim 1, wherein said dislocation bundle concentration regions are randomly disposed in a surface of said n-type nitride semiconductor substrate.

8. A method of manufacturing the nitride semiconductor light emitting element as recited in claim 1, comprising:
forming said nitride semiconductor stacked body by stacking said n-type nitride semiconductor layer, said active layer, and said p-type nitride semiconductor layer in this order on said n-type nitride semiconductor substrate including said dislocation bundle concentration region;
forming a hole in said nitride semiconductor stacked body by etching the region of said nitride semiconductor stacked body corresponding to said dislocation bundle concentration region; and
forming said dielectric region by embedding a dielectric in said hole in said nitride semiconductor stacked body.

9. The method of manufacturing the nitride semiconductor light emitting element according to claim 8, wherein said etching is performed by wet-etching said nitride semiconductor stacked body using an aqueous solution of potassium hydroxide.
